(19) United States
(12) Patent Application Publication
(10) Pub. No.: US 2024/0349516 A1
(43) Pub. Date: Oct. 17, 2024

(54) Semiconductor structure and test method thereof

(71) Applicant: United Semiconductor (Xiamen) Co., Ltd., Xiamen (CN)

(72) Inventors: XIONGBO PAN, Shamen City (CN); WEN YI TAN, Xiamen (CN)

(73) Assignee: United Semiconductor (Xiamen) Co., Ltd., Xiamen (CN)

(21) Appl. No.: 18/198,829

(22) Filed: May 17, 2023

(30) Foreign Application Priority Data
Apr. 14, 2023 (CN) 202310402268.7

(51) Int. Cl. H10B 63/00; H10B 63/10

(52) U.S. Cl. CPC H10B 63/80; H10B 63/10

(57) ABSTRACT

The invention provides a semiconductor structure, which comprises a material layer, wherein a plurality of resistive random access memory cells are arranged on the material layer in an array, the array comprises a first outer ring, the first outer ring consists of some of the plurality of resistive random access memory cells and is located at the outermost ring of the array, and a peripheral metal layer, which at least connects a plurality of resistive random access memory cells located in the first outer ring in series into a loop.

### BACKGROUND OF THE INVENTION

### 1. Field of the Invention

The invention relates to the field of semiconductors, in particular to a test pattern structure of a resistive random access memory (RRAM) cell and a manufacturing method thereof.

### 2. Description of the Prior Art

Resistive random access memory (RRAM) has the advantages of simple structure, low operating voltage, high operating speed, good durability and compatibility with CMOS process. RRAM is the most promising substitute for traditional flash memory, so as to achieve the purpose of reducing the device size. RRAM is being widely used in various components such as optical disks and nonvolatile memory arrays.

RRAM cells store data in a material layer that can be induced to change phase. In all or part of the layers, the material can induce a phase change and switch between a high-resistance state and a low-resistance state. After different resistance states are detected, they can be expressed as “0” or “1”. In a typical RRAM cell, the data storage layer consists of amorphous metal oxide. After applying enough voltage, the voltage can form a metal bridge across the data storage layer, thus forming a low resistance state. Then, all or part of the metal structure can be decomposed or melted by applying pulses with high current density or in other ways, so that the metal bridge is broken and the high resistance state is restored. Then when the data storage layer cools rapidly, it will change from high resistance state to low resistance state again.

### SUMMARY OF THE INVENTION

The invention provides a semiconductor structure, which comprises a material layer, a plurality of resistive random access memory cells are arranged on the material layer in an array, wherein the array comprises a first outer ring, the first outer ring consists of some of the plurality of resistive random access memory cells and is located at the outermost ring of the array, and a peripheral metal layer, and the peripheral metal layer at least connects a plurality of resistive random access memory cells located in the first outer ring in series into a loop.

The invention further provides a method for testing a semiconductor structure includes providing a material layer, forming a plurality of resistive random access memory cells arranged on the material layer in an array, wherein the array includes a first outer ring, the first outer ring consists of some of the plurality of resistive random access memory cells and is located at the outermost ring of the array, and forming a peripheral metal layer, wherein the peripheral metal layer at least connects the plurality of resistive random access memory cells located in the first outer ring in series into a loop.

The invention is characterized in that, in the array formed by RRAM cells, at least the outermost RRAM cells are connected in series with long metal line segments to form a loop. In this way, the formation quality of each RRAM cell in the outermost ring can be quickly judged by power-on test. Different from the prior art, in the prior art, the RRAM cells located at the periphery are usually regarded as dummy cells without forming conductive lines on them, while in the present invention, the RRAM cells located at the outer ring are used as test elements, and since the short metal line segments and the long metal line segments can be made together with the second metal layer, a test structure can be formed without additional process, so as to further improve the quality of semiconductor devices.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows a schematic cross-sectional structure of a resistive random access memory (RRAM) cell on a contact structure.

FIG. 2 shows a schematic cross-sectional structure of a resistive random access memory (RRAM) cell that may be generated after being over-etched.

FIG. 3 shows a top view of a plurality of RRAM cells arranged in an array and formed on a material layer.

FIG. 4 is a schematic diagram showing a top view after forming a second metal layer on the RRAM cells array according to a preferred embodiment of the present invention.

FIG. 5 is a schematic view from above after the loop (test line) is marked in FIG. 4.

FIG. 6 and FIG. 7 are schematic views of the cross-sectional structure taken along the section lines A-A′ and B-B′ in FIG. 4, respectively.

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and the effects to be achieved.

Please note that the figures are only for illustration and the figures may not be to scale. The scale may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

The semiconductor device provided by the invention at least comprises a plurality of resistive random access memory (RRAM) cells, and each RRAM cell is located on a contact structure. The contact structure may be located in an intermetallic dielectric (IMD). The following paragraphs describe the features of this case concisely. First, a schematic diagram of a single RRAM cell electrically connected to a contact structure is drawn.

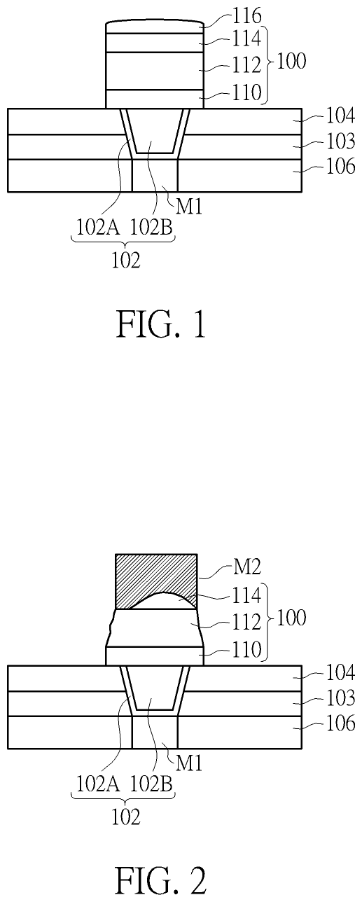

Please refer to FIG. 1, which shows a schematic cross-sectional structure of a resistive random access memory (RRAM) cell on a contact structure. As shown in FIG. 1, a resistive random access memory (RRAM) cell 100 is first provided and electrically connected to a contact structure 102. The contact structure 102 may be located in a single layer or a plurality of dielectric layers, and the lower part of the contact structure 102 may be electrically connected with another contact structure or wire. Taking this embodiment as an example, the contact structure 102 is located in a dielectric layer 103 and a dielectric layer 104, the dielectric layer 103 such as a nitrogen doped carbide (NDC) layer, and the dielectric layer 104 such as a silicon oxide layer, a silicon nitride layer and a silicon oxynitride layer. The contact structure 102 comprises a pad layer 102A located at the bottom and a conductive layer 102B located above, wherein the pad layer 102A is, for example, titanium nitride (TiN) or tantalum nitride (TaN), etc. The pad layer 102A is formed first, and the conductive layer 102A formed subsequently can be preferably formed on the pad layer 102A, and the material of the conductive layer 102a can include metals such as tungsten, cobalt, copper, aluminum or other conductive materials. The present invention is not limited thereto.

Please continue to refer to FIG. 1. Under the contact structure 102, another first metal layer M1 is located in an inter-metal dielectric (IMD) layer 106, and the contact structure 102 is electrically connected with the first metal layer M1. The first metal layer M1 and the contact structure 102 are, for example, wires or conductive vias located in the IMD. The first metal layer M1 may be one of multiple metal layers in a semiconductor stacked structure, and electronic components such as transistors may be connected below it. For the sake of simplicity, other material layers or electronic components under the first metal layer M1 are not shown here, but those skilled in the art should understand that other electronic components or material layers may be included below the semiconductor structure shown in FIG. 1.

Referring to FIG. 1, a resistive random access memory (RRAM) cell 100 is located on a contact structure 102 and a dielectric layer 104, and the RRAM cell 100 electrically connected to the contact structure 102. Generally speaking, the resistive random access memory cell 100 may at least include a lower electrode 110, a resistive switching layer 112 and a top electrode 114 stacked in sequence.

The bottom electrode 110 and the top electrode layer 114 can have any suitable composition and can be formed by any suitable process. Examples of suitable compositions include, without limitation, metals, metal nitrides, and doped polysilicon, or the combination thereof. In some embodiments, the bottom electrode 110 and the top electrode layer 114 include metals. The metal could be, for example, Al, Ti, Ta, Au, Pt, W, Ni, Ir, or Cu. In some embodiments, the bottom electrode 110 and the top electrode layer 114 include metal nitride. The metal nitride could be, for example, titanium nitride (TiN), tantalum nitride (TaN) or tungsten nitride (WN). In some embodiments, the bottom electrode 110 and the top electrode layer 114 include doped polysilicon. A doped polysilicon can be either a p+ doped polysilicon or an n+ doped polysilicon. Besides, the bottom electrode 110 and the top electrode layer 114 may include identical material or different materials, and the present invention is not limited thereto.

The material of the switching resistance layer 112 can be any material suitable for the data storage layer of an RRAM cell. A material suitable for the data storage layer of an RRAM cell is one that can be induced to undergo a reversible phase change between a high resistance state and a low resistance state. In some embodiments, the phase change is between an amorphous state and a metallic state. The phase change can be accompanied by or associated with a change in chemical composition. In most embodiments, the resistive switching layer 112 is a high-k dielectric while in the low resistance state. In some embodiments, the resistive switching layer 112 is a transitional metal oxide. Examples of materials that can be suitable for the switching resistance layer 114 include such as titanium oxide, nickel oxide (NiO), tungsten oxide (WO₃), zirconium oxide (ZrO), copper oxide (CuO), hafnium oxide (HfO), tantalum oxide (TaO), zinc oxide (ZnO), aluminum oxide (Al₂O₃), molybdenum oxide (MoO), but not limited thereto. In most embodiments, the thickness of the resistive switching layer 112 is in the range from 20 angstroms to 100 angstroms. In some embodiments, the thickness of the resistive switching layer 112 is in the range from 30 angstroms to 70 angstroms, for example, 50 angstroms.

In addition, except for the above materials, the resistive random access memory cell 100 may also include more material layers, which is also within the scope of the present invention. For example, before forming the lower electrode 110, a diffusion barrier layer (not shown) can be optionally additionally formed on the contact structure 102, and then the lower electrode 110 can be formed on the diffusion barrier layer. The diffusion barrier layer may prevent the material of the contact structure 102 from contaminating the lower electrode. In some embodiments, the contact structure 102 contains copper, and the lower electrode 110 is a material easily contaminated by copper, such as titanium nitride (TiN) or tantalum nitride (TaN). At this time, the diffusion barrier layer can be selected from metals, conductive oxides, nitrides or nitrogen oxides composed of aluminum, manganese, cobalt, titanium, tantalum, tungsten, nickel, tin and magnesium. Or in other embodiments of the present invention, other material layers, such as metal layers, may be included above or below the resistive switching layer 112. However, it should be noted that the above structure is only one example of the present invention, and the resistive random access memory cells made of other materials also belong to the scope of the present invention.

Next, a patterned mask layer 116 is formed on the top electrode 114. The patterned mask layer 116 is made of silicon nitride or silicon oxide, for protecting the resistive random access memory cell 100.

In addition, the structure of the present invention may also include spacers (not shown) located at sidewalls of the RRAM cell 100. The conventional technology in which the spacer belongs to the field is therefore omitted and not shown in the drawing. In addition, the details of materials and fabrication methods of other resistive random access memory cells are also known in the art, so they are not detailed here.

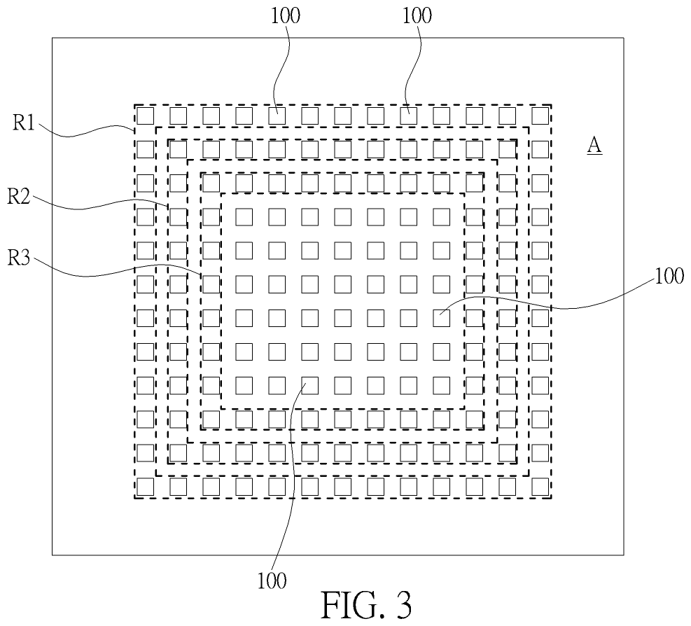

FIG. 2 shows a schematic cross-sectional structure of a resistive random access memory (RRAM) cell that may be generated after being over-etched. As shown in FIG. 2, in the subsequent process, in order to electrically connect the RRAM cell 100 with other metal layers, for example, to form a second metal layer M2 to electrically connect the RRAM cell 100, it may be possible to remove the patterned mask layer 116 by etching processes or the like, and then form a contact structure (the second metal layer M2) and other elements to electrically connect the top electrode 114. However, in some processes, due to poor control of etching parameters, excessive etching may occur when removing the patterned mask layer 116, and other underlying material layers (such as the top electrode 114, the resistive switching layer 112, the lower electrode 110, etc.) may be partially etched, which will damage the structure of the RRAM cell 100 and be detrimental to the electricity of the second metal layer M2 and the RRAM cell 100.

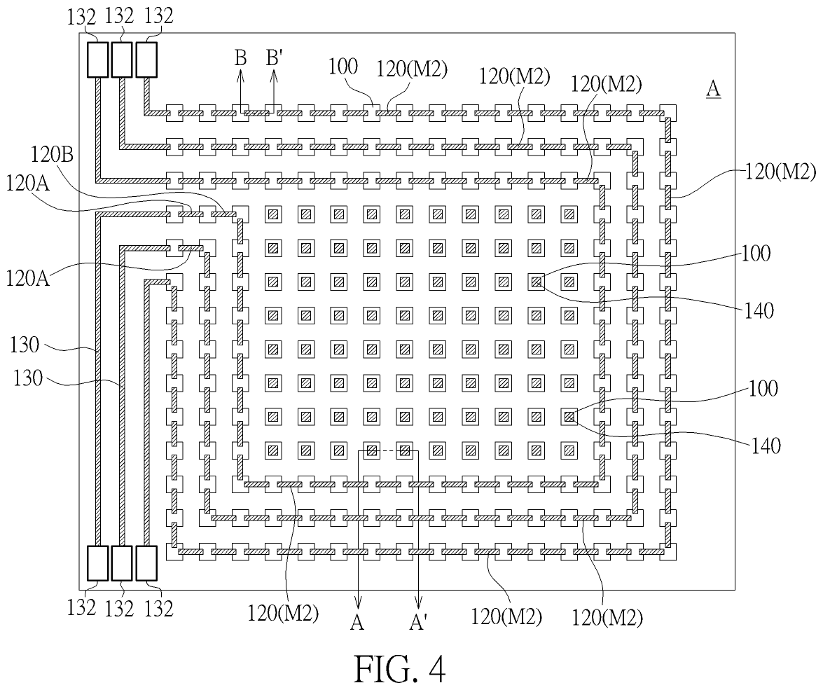

FIG. 3 shows a top view of a plurality of RRAM cells arranged in an array and formed on a material layer. In the actual manufacturing process, a plurality of the RRAM cells 100 are usually formed in one process and disposed on the material layers (such as the dielectric layer 104 and the first metal layer M1) and arranged in an array. Because of the large number of RRAM cells 100, it will take too much time to observe whether the RRAM cells 100 are over-etched by means of electron microscope (such as TEM or SEM, etc.).

Please note that the complete RRAM array is not drawn in FIG. 3 for the sake of simplicity, and only a part of the RRAM array is drawn in FIG. 3, and the size and shape of the RRAM array are not limited to that shown in FIG. 3. For example, the number of RRAM cells contained in the RRAM array and the spacing between RRAM cells can be adjusted according to actual requirements.

First, the first outer ring R1, the second outer ring R2 and the third outer ring R3 in the RRAM array shown in FIG. 3 are defined. The first outer ring R1 is the outermost ring area in the RRAM array, and the first outer ring R1 contains a plurality of RRAM cells 100, that is to say, each RRAM cell 100 of the first outer ring R1 is adjacent to the isolation area A around the RRAM array. In other words, any RRAM cell 100 in the first outer ring R1 has no other RRAM cell located between the selected RRAM cell 100 and the isolation area A in the direction of the connecting line between the RRAM cell 100 and the central point of an RRAM array.

As shown in FIG. 3, the second outer ring R2 is an area adjacent to and surrounded by the first outer ring R1, that is to say, the second outer ring R2 is a secondary outer ring area in the whole RRAM array, and it is the area closest to the isolation area A except the first outer ring R1. Similarly, the third outer ring R3 is an area adjacent to and surrounded by the second outer ring R2.

According to the applicant's observation, the degree of etching of the plurality of RRAM cells 100 arranged in an array will be slightly different after the etching step. More specifically, due to the loading effect of the etching process, the RRAM cell 100 near the edge of the RRAM array will be etched seriously because it is adjacent to the isolation area A. That is, the RRAM cells 100 included in the first outer ring R1, the second outer ring R2 and even the third outer ring R3 are prone to over-etching. In contrast, the RRAM cell 100 near the central area of the array is less prone to over-etching.

In the conventional steps, each RRAM cell located around the RRAM array may be used as a dummy cell or a redundant cell, that is, because these cells are easily damaged, the second metal layer M2 will not be formed on these surrounding RRAM cells.

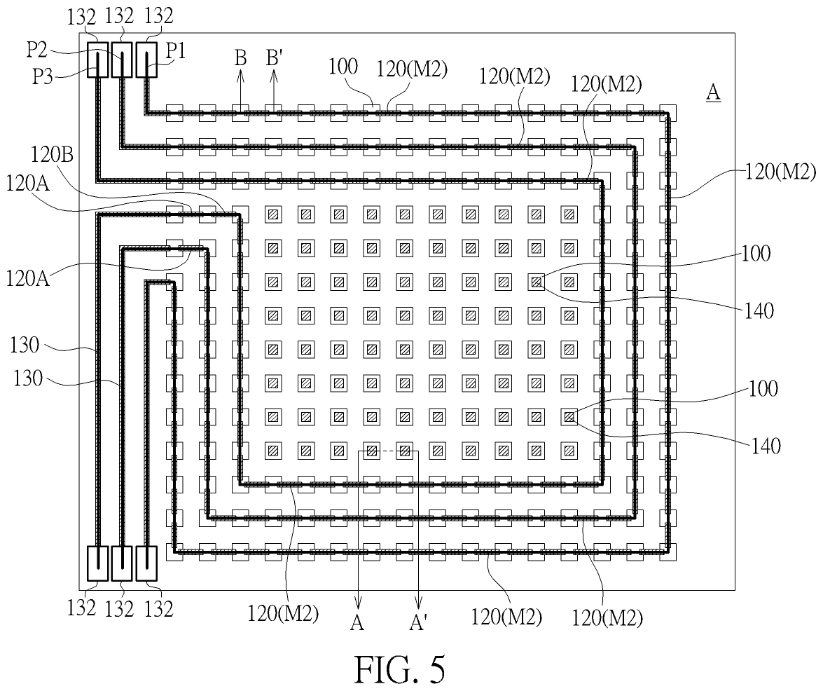

FIG. 4 is a schematic diagram showing a top view after forming a second metal layer on the RRAM cells array according to a preferred embodiment of the present invention. In the preferred embodiment of the present invention, the second metal layer M2 includes a plurality of short metal line segments 120, a plurality of long metal line segments 130, a plurality of contact pads 132 and a plurality of contact posts 140. The short metal line segments 120, the long metal line segments 130, the contact pads 132 and the contact posts 140 can all belong to the second metal layer M2, that is to say, they can be formed by the same process and located in the same dielectric layer or possibly located on the same horizontal plane, and the materials can include metals such as tungsten, cobalt, copper, aluminum or other conductive materials. In this embodiment, each short metal line segment 120 is located in the first outer ring R1, the second outer ring R2 and the third outer ring R3, and the short metal line segment 120 spans between two RRAM cells 100 and electrically connects two adjacent RRAM cells 100.

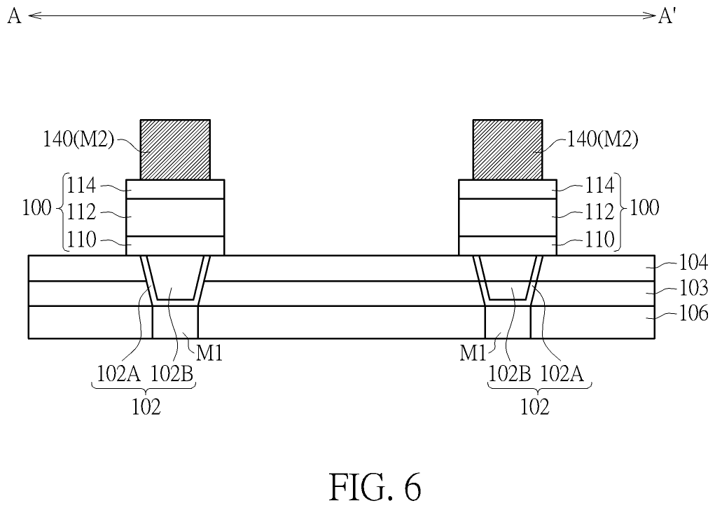

Please refer to FIG. 5, which shows the schematic diagram of the top view after the loop (test line) is marked in FIG. 4. The short metal line segments 120 located in the first outer ring R1 connects the RRAM cells 100 in the first outer ring R1 in series to form a loop (or test line) P1. Similarly, the short metal line segments 120 located in the second outer ring R2 connects the RRAM cells 100 in the second outer ring R2 in series to form another loop (or test line) P2, and the short metal line segments 120 located in the third outer ring R3 connects the RRAM cells 100 in the third outer ring R3 in series to form another loop (or test line) P3.

A plurality of long metal line segments 130 are respectively connected to the loops P1, P2 and P3 formed by the first outer ring R1, the second outer ring R2 and the third outer ring R3. It is worth noting that one end of a plurality of long metal line segments 130 may be connected with different RRAM cells 100 in the first outer ring R1. And a part of the short metal line segment 120 (such as the short metal line segment 120A as shown in FIG. 4) spanning between the RRAM cell 100 of the first outer ring R1 and the RRAM cell 100 of the second outer ring R2 to electrically connected to the loop of the second outer ring R2, or a part of the short metal line segment 120 (such as the short metal line segment 120B as shown in FIG. 4) spanning between the RRAM cell 100 of the second outer ring R2 and the RRAM cell 100 of the third outer ring R3 to electrically connected to the loop of the third outer ring R3. The other end of the long metal line segment 130 is connected to the contact pad 132.

Alternatively, in other embodiments of the present invention, the line pattern can be changed so that the long metal line segment 130 is directly connected to the RRAM cell 100 of the second outer ring R2 or the third outer ring R3 (i.e., without passing through the first outer ring R1), which is also within the scope of the present invention.

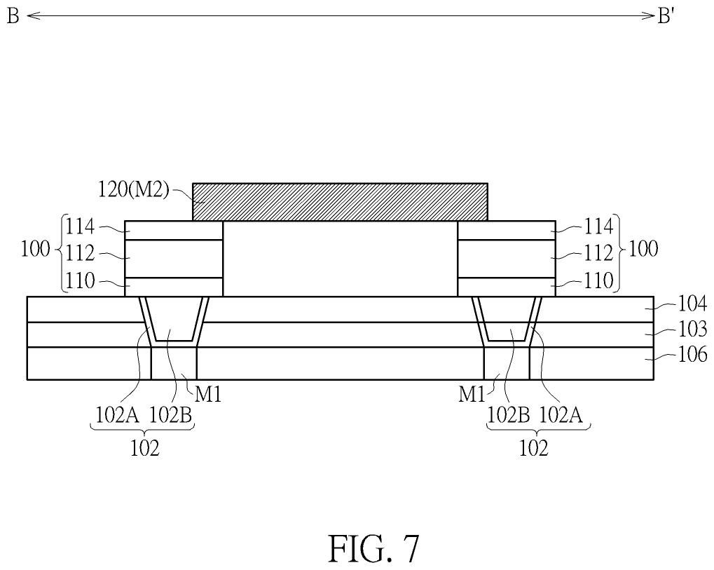

In this embodiment, except for the first outer ring R1, the second outer ring R2 and the third outer ring R3, the rest of the RRAM cells 100 located in the central part of the RRAM array are connected to contact posts 140, where the contact posts 140 are, for example, contact structures or via contacts in the semiconductor manufacturing process. Please refer to FIG. 6 and FIG. 7 together, which respectively show the schematic cross-sectional structure taken along section line A-A′ and B-B′ in FIG. 4. The contact post 140 described here and the short metal line segment 120 or the long metal line segment 130 both belong to a part of the second metal layer M2, but the difference between them is that each contact post 140 is located on an RRAM cell 100 (as shown in FIG. 6), and the contact post 140 can be electrically connected with other electronic components in the subsequent process. That is, the contact posts 140 in FIG. 6 are independent of each other (they do not span between two RRAM cells 100 in the current dielectric layer). Each of the above short metal segments 120 spans two RRAM cells 100 (as shown in FIG. 7) at the same time, while the long metal segment 130 extends into the isolation area A, and the short metal segment 120 and the long metal segment 130 will not be electrically connected with other electronic components in the subsequent process.

In this embodiment, a plurality of short metal line segments 120, long metal line segments 130 and contact pads 132 connect a plurality of RRAM cells 100 of the first outer ring R1, the second outer ring R2 and the third outer ring R3 in series into loops P1, P2 and P3. The loop here can also be regarded as a test line. As shown in FIG. 5, a plurality of RRAM cells 100 are connected in series into three test lines separated from each other. Taking the loop (or test line) P1 of the first outer ring R1 as an example, the loop P1 connects most of the RRAM cells 100 in the first outer ring R1, so the user can apply voltage to the contact pad 132 to energize the loop P1 to determine whether most of the RRAM cells 100 in the first outer ring R1 have a complete structure. For example, observe whether the loop P1 of the first outer ring R1 is open after the voltage is applied. If it is open, it may mean that at least one or more RRAM cells 100 in the first outer ring R1 have been damaged. For example, the electrodes of some RRAM cells 100 are damaged due to over-etching, and the path cannot be successfully formed. In this way, users can immediately find the defects in the process and carry out an adjustment process step, such as resetting the etching parameters. Similarly, the loop P2 of the second outer ring R2 and the loop P3 of the third outer ring R3 can also be tested in the same way.

It is worth noting that the first outer ring R1, the second outer ring R2, the third outer ring R3 and other RRAM cells 100 located in the central area in the present invention all belong to the same RRAM array. Therefore, the first outer ring R1, the second outer ring R2 and the third outer ring R3 are different from the test key in the prior art. The test key in the prior art may be formed in other areas instead of being formed together with and around the main element area.

In addition, although the first outer ring R1, the second outer ring R2 and the third outer ring R3 are defined in the above embodiment and three different loops are formed respectively, the present invention can adjust the number of outer rings and loops, and it can be within the scope of the present invention as long as the RRAM cell 100 of at least one outer ring is connected in series into a loop.

Based on the above description and drawings, the present invention provides a semiconductor structure, which comprises a material layer (dielectric layer 104), and a plurality of RRAM cells 100 are arranged on the material layer in an array, the array comprises a first outer ring R1, which is composed of some of the plurality of RRAM cells 100 and located at the outermost ring of the array. A peripheral metal layer (i.e., a loop formed by the first outer ring R1), the peripheral metal layer at least connects a plurality of resistive random access memory cells 100 located in the first outer ring R1 in series to form a loop.

In some embodiments of the present invention, the resistive random access memory cell 100 includes a lower electrode 110, a resistive switching layer 112 and a top electrode 114 stacked in sequence.

In some embodiments of the present invention, the peripheral metal layer includes a plurality of short metal line segments 120, each of which spans the top electrodes 110 of two resistive random access memory cells 100.

In some embodiments of the present invention, the peripheral metal layer further comprises a long metal line segment 130, wherein one end of the long metal line segment 130 is electrically connected to a resistive random access memory cell 100.

In some embodiments of the present invention, the peripheral metal layer further comprises a contact pad 132, which is electrically connected to the other end of the long metal line segment 130.

In some embodiments of the present invention, a plurality of contact posts 140 are further included to electrically connect the top electrodes 110 of other plurality of resistive random access memory cells 100 in the array.

In some embodiments of the present invention, each contact post 140 only contacts the top electrode 110 of one of the resistive random access memory cells 100.

In some embodiments of the present invention, a bottom metal layer (the first metal layer M1) is further included, which is electrically connected to the lower electrodes 110 of each of the plurality of resistive random access memory cells 100.

In some embodiments of the present invention, the array further includes a second outer ring R2, which is composed of some of the plurality of resistive random access memory cells 100, the second outer ring R2 is adjacent to the first outer ring R1, and the second outer ring R2 is located inside the first outer ring R1 of the array, and further includes a second peripheral metal layer (i.e., a loop formed by the second outer ring R2), and the second peripheral metal layer will at least include a plurality of resistive random access memory cells 100 in the second outer ring R2 in series into another loop P2.

The invention also provides a method for testing a semiconductor structure, which comprises providing a material layer (dielectric layer 104) and forming a plurality of resistive random access memory cells 100 arranged on the material layer 104 in an array, wherein the array comprises a first outer ring R1, which is composed of a part of a plurality of resistive random access memory cells 100 and located at the outermost ring of the array to form a peripheral metal layer, and the peripheral metal layer will at least be located in the first outer ring R1.

In some embodiments of the present invention, it further includes applying a voltage to the contact pad 132 and testing whether the loop is open.

In some embodiments of the present invention, if the loop is open, an adjustment process step is performed.

The invention is characterized in that, in the array formed by RRAM cells, at least the outermost RRAM cells are connected in series with long metal line segments to form a loop. In this way, the formation quality of each RRAM cell in the outermost ring can be quickly judged by power-on test. Different from the prior art, in the prior art, the RRAM cells located at the periphery are usually regarded as dummy cells without forming conductive lines on them, while in the present invention, the RRAM cells located at the outer ring are used as test elements, and since the short metal line segments and the long metal line segments can be made together with the second metal layer, a test structure can be formed without additional process, so as to further improve the quality of semiconductor devices.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor structure, comprising:
a material layer;
a plurality of resistive random access memory cells are arranged on the material layer in an array, wherein the array comprises a first outer ring, and the first outer ring consists of some of the plurality of resistive random access memory cells and is located at the outermost ring of the array; and
a peripheral metal layer, at least connects the plurality of resistive random access memory cells located in the first outer ring in series into a loop.

2. The semiconductor structure according to claim 1, wherein each resistive random access memory cell comprises a lower electrode, a resistive switching layer and a top electrode stacked in sequence.

3. The semiconductor structure according to claim 2, wherein the peripheral metal layer comprises a plurality of short metal line segments, wherein each short metal line segment spans the top electrodes of two resistive random access memory cells.

4. The semiconductor structure according to claim 3, wherein the peripheral metal layer further comprises a long metal line segment, wherein one end of the long metal line segment is electrically connected to a resistive random access memory cell.

5. The semiconductor structure according to claim 4, wherein the peripheral metal layer further comprises a contact pad electrically connected to the other end of the long metal line segment.

6. The semiconductor structure according to claim 2, further comprising a plurality of contact posts electrically connected to the top electrodes of other resistive random access memory cells in the array.

7. The semiconductor structure according to claim 6, wherein each contact post only contacts the top electrode of one of the resistive random access memory cells.

8. The semiconductor structure according to claim 2, further comprising a bottom metal layer electrically connected to the lower electrodes of each of the plurality of resistive random access memory cells.

9. The semiconductor structure according to claim 1, wherein the array further comprises a second outer ring, which is composed of some of the plurality of resistive random access memory cells, wherein the second outer ring is adjacent to the first outer ring, and wherein the second outer ring is located inside the first outer ring of the array, and the semiconductor structure further comprises a second peripheral metal layer, which at least connects the plurality of resistive random access memory cells located in the second outer ring in series into another loop.

10. A method for testing a semiconductor structure, comprising:
providing a material layer;
forming a plurality of resistive random access memory cells arranged on the material layer in an array, wherein the array comprises a first outer ring, and the first outer ring consists of some of the plurality of resistive random access memory cells and is located at the outermost ring of the array; and
forming a peripheral metal layer which at least connects the plurality of resistive random access memory cells in the first outer ring in series to form a loop.

11. The method for testing a semiconductor structure according to claim 10, wherein the resistive random access memory cell comprises a lower electrode, a resistive switching layer and a top electrode stacked in sequence.

12. The method for testing a semiconductor structure according to claim 11, wherein the peripheral metal layer comprises a plurality of short metal line segments, wherein each short metal line segment spans the top electrodes of two resistive random access memory cells.

13. The method for testing a semiconductor structure according to claim 12, wherein the peripheral metal layer further comprises a long metal line segment, wherein one end of the long metal line segment is electrically connected to a resistive random access memory cell.

14. The method for testing a semiconductor structure according to claim 13, wherein the peripheral metal layer further comprises a contact pad electrically connected to the other end of the long metal line segment.

15. The method for testing a semiconductor structure according to claim 14, further comprising applying a voltage to the contact pad and testing whether the loop is open.

16. The method for testing a semiconductor structure according to claim 15, wherein if the loop is open, an adjustment process step is performed.

17. The method for testing a semiconductor structure according to claim 11, further comprising forming a plurality of contact posts electrically connected to the top electrodes of other resistive random access memory cells in the array.

18. The method for testing a semiconductor structure according to claim 17, wherein each contact post only contacts the top electrode of one of the resistive random access memory cells.

19. The method for testing a semiconductor structure according to claim 11, further comprising a bottom metal layer electrically connected to the lower electrodes of each of the plurality of resistive random access memory cells.

20. The test method of semiconductor structure as claimed in claim 10, wherein the array further comprises a second outer ring, which is composed of some of the plurality of resistive random access memory cells, wherein the second outer ring is adjacent to the first outer ring, and wherein the second outer ring is located inside the first outer ring of the array, and the semiconductor structure further comprises a second peripheral metal layer, which at least connects the plurality of resistive random access memory cells located in the second outer ring in series into another loop.
